(19) United States
(12) Patent Application Publication
(10) Pub. No.: US 2023/0376651 A1
(43) Pub. Date: Nov. 23, 2023

(54) GENERATING WEATHER SIMULATIONS BASED ON SIGNIFICANT EVENTS

(71) Applicant: INTERNATIONAL BUSINESS MACHINES CORPORATION, ARMONK, NY (US)

(72) Inventors: Bianca Zadrozny, RIO DE JANEIRO (BR); Campbell D Watson, Brooklyn, NY (US); Dario Augusto Borges Oliveira, Paraíso (BR); Jorge Luis Guevara Diaz, Sao Paulo (BR)

(21) Appl. No.: 17/663,917

(22) Filed: May 18, 2022

(51) Int. Cl. G06F 30/27; G01W 1/10

(52) U.S. Cl. CPC G06F 30/27; G01W 1/10

(57) ABSTRACT

A method, computer system, and a computer program for generating weather simulations based on significant events is provided. The present invention may include receiving a plurality of environmental data associated with a geographic area. The present invention may then include retrieving one or more data feeds including a plurality of events. The present invention may further include associating the plurality of events with a subset of the plurality of environmental data. The present invention may further include generating a knowledge graph for the geographic area based on the association.

### BACKGROUND

The present invention relates generally to weather prediction, and in particular, to generating weather simulations based on significant weather events.

Analysis of various types of data such as historical climate data, topography data, and crowdsourced weather data allow not only the real-time conditions of a geographic location to be ascertained, but also enables the prediction of weather conditions and generation of simulated weather scenarios for the geographic location. This information can be vital in order for individuals to be prepared for and/or circumvent climate-related hazards such as heat waves, cold waves, blizzards, tornadoes, lightning storms, flooding, etc. Current systems are able to generate weather simulations for a geographic area; however, said systems are not configured to render weather simulations which account for correlations between historical weather data and significant events ascertained from internet-based sources such as social media, which show weather occurring in real-time. This limitation impacts the accuracy and efficiency of simulations due to the historical climate data not being configured to account for the underlying significant event that is the cause and/or effect of the data.

### SUMMARY

Additional aspects and/or advantages will be set forth in part in the description which follows and, in part, will be apparent from the description, or may be learned by practice of the invention.

Embodiments of the present invention disclose a method, system, and computer program product for simulating weather. A computer receives a plurality of environmental data associated with a geographic area. The computer retrieves one or more data feeds including a plurality of real-time events. The computer associates the plurality of real-time events with a subset of the plurality of environmental data, and generates a knowledge graph for the geographic area based on the association. With this embodiment, the knowledge graph is configured to support generation of a weather simulation associated with the geographic area for a period of time in the future.

### BRIEF DESCRIPTION OF THE DRAWINGS

These and other objects, features, and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a functional block diagram illustrating a computational environment for generating weather simulations according to at least one embodiment;

FIGS. 2A-B illustrates an exemplary block diagram illustrating a data flow associated with the environment of FIG. 1, according to at least one embodiment;

FIG. 3 is a diagram of an exemplary knowledge graph in accordance with aspects of the present invention.

FIG. 4 illustrates a flowchart illustrating a process for generating weather simulations based on significant events according to at least one embodiment;

FIG. 5 depicts a block diagram illustrating components of the software application of FIG. 1, in accordance with an embodiment of the invention; and

FIG. 6 depicts a cloud-computing environment, in accordance with an embodiment of the present invention

FIG. 7 depicts abstraction model layers, in accordance with an embodiment of the present invention.

### DETAILED DESCRIPTION

The descriptions of the various embodiments of the present invention will be presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

It should be understood that the Figures are merely schematic and are not drawn to scale. It should also be understood that the same reference numerals are used throughout the Figures to indicate the same or similar parts.

In the context of the present application, where embodiments of the present invention constitute a method, it should be understood that such a method is a process for execution by a computer, i.e. is a computer-implementable method. The various steps of the method therefore reflect various parts of a computer program, e.g. various parts of one or more algorithms.

Also, in the context of the present application, a system may be a single device or a collection of distributed devices that are adapted to execute one or more embodiments of the methods of the present invention. For instance, a system may be a personal computer (PC), a server or a collection of PCs and/or servers connected via a network such as a local area network, the Internet and so on to cooperatively execute at least one embodiment of the methods of the present invention.

The following described exemplary embodiments provide a method, computer system, and computer program product for generating weather simulations based on real-time events occurring in a data feed. Current weather simulations are not constrained to the significant/impactful event that is the cause and/or effect of the applicable climate associated with the simulation. Historical climate data alone may allow prediction of the weather of a geographical area; however, the cause and the impact of the prediction may not be ascertained from this data. For example, the predicted temperature and precipitation of the geographic area for a period of time may be ascertained via one or more simulations; however, the underlying significant events that may be the cause and/or effect of the historical climate data such as high precipitation causing floods and retail losses are not accounted for, and no association can be made. This gap in information not only prevents the ability to generate efficient risk models, but more importantly creates social, economic, political, and other applicable impacts that may be circumvented via the weather simulations generated by the present invention. Moreover, conventional extreme weather warning/prediction systems identify geographies, typically at the granularity of suburbs or local government areas, which is inherently risky as being inaccurate for being too specific of an area. These aforementioned systems generate specific weather simulations accounting for historical climate data, in which integration of additional data would require additional computing resources for collection and processing of said additional data, and this would conventionally not be scalable for generating weather simulations across geographic areas in real-time. As such, the present embodiments have the capacity to generate optimized weather simulations for a geographic area accounting for significant events, in addition to doing so in a manner that circumvents the aforementioned issues by utilizing unconventional geo-based spatio-temporal data in order to render knowledge graphs for geographic areas including inferences necessary for optimized weather simulations. Said knowledge graphs and derived data may increment precision and improve various technologies including but not limited to catastrophic weather events planning systems, risk/flood analyses, warning systems, etc. Thus, the present embodiments provided herein are configured to not only improve the field of weather predictions by optimizing weather simulations, but also the field of computing overall by providing generation and utilization of unconventional data types, using machine learning models, configured to reduce the amount of computing resources required to collect, process, and utilize various types of data for generating weather simulations.

Embodiments for the present invention allow for generation of a plurality of knowledge graphs pertaining to a geographic area based on the association of a plurality of environmental data associated with the geographic area and a plurality of events derived from one or more data feeds, in which the knowledge graphs include one or more simulations pertaining to the geographic area. Embodiments of the present invention extract the plurality of events from the data feeds based on metadata indicating that the plurality of events pertain to the geographic area, and cluster the plurality of events based on multiple factors including, but not limited to one or more components of the events, data derived from user inputs, applied weights, and/or one more similarity scores.

As described herein, the term ‘knowledge graph’ may denote a data structure or series of data structures with one or more nodes each comprising facts—represented in the one or more nodes—and edges—representing connections or links between the nodes and representing relationships between the one or more nodes. In some embodiments, the knowledge graph may represent a knowledge base for an organization of so-called unstructured data, i.e., facts, and their semantic relationships. The edges may be characterized by related attributes, e.g., describing the strength of a link between two connected nodes. Other applicable attributes, features, and analytics associated with knowledge graphs known to those of ordinary skill in the art may be used.

As described herein, the term “weather” is used to mean the state of the atmosphere at a geographic location and time regarding heat, dryness, sunshine, wind speed, wind direction, precipitation, flooding, earthquake, tsunami, typhoons, hurricanes, tornadoes, volcanic eruptions, a combination thereof, or any other applicable meteorological/geological related instances known to those of ordinary skill in the art.

As described herein, the term “geographic area” is any applicable land/water/air-based region influenced or impacted by weather. In some embodiments, the geographic area can be defined by geographic positions, such as geographic coordinates, global positioning coordinates, geospatial data, or any other applicable coordinates known to those of ordinary skill in the art.

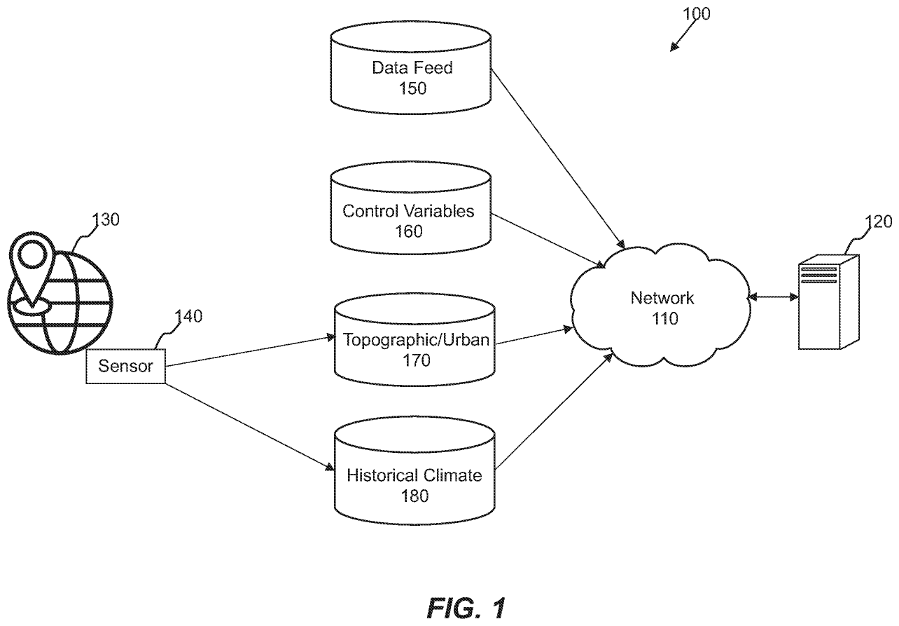

Referring now to FIG. 1, a weather simulation environment 100 is depicted, according to an exemplary embodiment. FIG. 1 provides only an illustration of implementation and does not imply any limitations regarding the environments in which different embodiments may be implemented. Modifications to environment 100 may be made by those skilled in the art without departing from the scope of the invention as recited by the claims. In some embodiments, environment 100 includes a server 120, a geographic area 130, at least one sensor 140, at least one data feed database 150, a control variables database 160, a topographic/urban database 160, and a historical climate database 180 (collectively referred to as the “databases”), in which each of the aforementioned systems and/or databases are communicatively coupled to server 120 over network 110. Network 110 may include various types of communication networks, such as a wide area network (WAN), local area network (LAN), a telecommunication network, a wireless network, a public switched network and/or a satellite network, etc. In some embodiments, network 110 may be embodied as a physical network and/or a virtual network. A physical network can be, for example, a physical telecommunications network connecting numerous computing nodes or systems such as computer servers and computer clients. A virtual network can, for example, combine numerous physical networks or parts thereof into a logical virtual network. In another example, numerous virtual networks can be defined over a single physical network. In some embodiments, network 110 is configured as public cloud computing environments, which can be providers known as public cloud services providers. Embodiments herein can be described with reference to differentiated fictitious public computing environment (cloud) providers such as ABC-CLOUD, ACME-CLOUD, MAGIC-CLOUD, and SUPERCONTAINER-CLOUD. The applicable computing devices of environment 100 may include one or more of a wearable device, a mobile device, a telephone, a personal digital assistant, a netbook, a laptop computer, a tablet computer, a desktop computer, or any applicable type of computing devices capable of running a program, accessing a network, and/or accessing the databases. It should be appreciated that FIG. 1 provides only an illustration of one implementation and does not imply any limitations with regard to the environments in which different embodiments may be implemented. Many modifications to the depicted environments may be made based on design and implementation requirements.

In some embodiments, sensor 140 is associated with one or more computing devices and/or a plurality of sensors (i.e., sensor networks/modules) configured to collect a plurality of environmental data associated with geographic area 130 in which the plurality of sensors may include but are not limited to cameras, weight scales, gas detectors, humidity sensors, accelerometers, gyroscopes, barometers, GPS sensors, thermometers, haptic sensors, biological-based sensors, or any other applicable sensors known to those of ordinary skill in the art. Sensor 140 may be associated with and/or be included in a crowdsourcing/crowd-sharing platform in which sensor 140 may collect media (e.g., images, videos, audio, etc.), crowdsourced navigation information (e.g., current traffic event data), GPS indexed historic crowdsourced traffic event data, GPS, indexed historical weather data, GPS indexed historical traffic event data, and current GPS location services data), topographical data, flooding data, crop damage data, soil composition data, and any other applicable data known to those of ordinary skill in the art derived from one or more applicable computing devices within or associated with geographic area 130. In some embodiments, sensor 140 may be associated with a weather module hosted by server 120 configured to upload current collected images of geographic area 130 to a permissioned crowdsourced stream integration of data sources and a crowd-share insight module hosted by server 120 designed to determine insights (e.g., one or more databases containing trends associated with historic crowdsourced traffic event data, historical weather data, historical traffic event data, and current GPS location services data) from one or more navigation based crowd sharing platforms. In other embodiments, the crowd-share insight module can store determined insights from one or more other predictive analytics model and artificial intelligence algorithms into the databases. It should be noted that the data collected and/or derived from server 120 and/or sensor 140 are configured to be stored into one or more of the databases.

It should be noted that data feed database 150 is configured to function as a repository for data collected via server 120 and/or one or more crawlers associated with server 120 configured to collect, extract, and prepare data sourced from one or more social media and/or media platforms (e.g, Facebook®, Twitter®, The Weather Channel®, blogs, local media, etc.). The one or more crawlers may be configured to detect content (e.g., news articles/videos/audio files) pertaining to a social, political, and/or economic matter associated with geographic area 130 based on the title and/or the content of the article, in which the one or more crawlers extract the applicable data from the media source and transmit the data to server 120 which ultimately stores the data within one or more of the databases. In some embodiments, data feed database 150 is continuously receiving text data, multi-media data, and any other applicable data known to those of ordinary skill in the art and server 120 is filtering the received data based upon the relevance to geographic area 130. For example, a media source may include an article entitled “Recent Flashfloods Impact The Global Economy” where geographic area 130 is mentioned, in which the one or more crawlers extract the applicable information for storage within data feed database 150. The extraction of events may be based on detection/analysis of metadata derived from content being traversed. For example, the metadata may be derived from social media content allowing the events to be extracted based on metadata indicating that the social media content and/or components thereof pertain to geographic area 130 in which said metadata includes but is not limited to GPS/location data, source information, file type, applicable social media interactions data (e.g., likes, comments, shares, re-posts), or any other applicable metadata known to those of ordinary skill in the art. In some embodiments, server 120 is configured to classify, tag, rank, and organize the received data in order to subsequently select the applicable data that aligns with data within the databases and/or data received from sensor 140. For example, in reference to the previous example, the applicable data relating to the flashfloods impacting geographic area 130 may be correlated via server 120 to weather data pertaining to geographic area 130 received and stored in historical climate database 180 during the same ascertainable time period as the article.

Control variables database 160 includes a plurality of control variables associated with weather including but not limited to precipitation level, atmospheric temperature, atmospheric pressure, wind speed, humidity, wind direction, applicable coordinates, and/or any other applicable data variable designed for the analysis of forces of nature in water bodies and land known to those of ordinary skill in the art. It should be noted that server 120 is configured to utilize data with the databases to ascertain the impact of changing environment conditions via measuring the effect of volatile environment conditions and accessing control variables database 160 to provide control variables that may be utilized to compensate for variations associated with geographic area 130.

Topographic/Urban database 160 includes elevation data, vegetation data, landmark location data, water features, soil data, topography parameters (e.g., slope, edges, curvatures, etc.) of geographic area 130, and/or any other applicable data pertaining to the natural and artificial physical features of an area known to those of ordinary skill in the art. In some embodiments, topographic/urban database 160 further includes environmental data, socioeconomic data, cartographic data, points of interest data, routing data, maneuvering data, government data (e.g., census data, open data, etc.), sensor data collected from sensor 140 associated with geographic area 130, or any other applicable data pertaining to urban environments known to those of ordinary skill in the art.

Historical climate database 180 includes precipitation data, relative humidity data, wind speed data, proprietary weather forecasts, or any other applicable ascertainable weather data known to those of ordinary skill in the art. In some embodiments, historical climate database 180 further includes pressure data, growth degree unit data, solar radiance data, and/or aggregation of such factors over a time period using functions, such as minimum, maximum, median, mean, and/or standard deviation.

Server 120 is designed to receive a plurality of signals from sensor 140 over network 110 in which the signals are time series signals received over a plurality of windows of time. A time series may, for example, be a sequence of data points, measured typically at successive time instants spaced at uniform time intervals. The time series may comprise pairs or tuples reflecting time and value. The values of time series may be derived from sensor data of sensor 140, signals, data within the databases, and/or data associated with server 120. In some embodiments, the signals of a time series may comprise values and a measurand in which the measurand may be a physical quantity, quality, condition, or property being measured. In some embodiments, the time series data and/or components of the received plurality of signals are configured to be stored in the databases. It should be noted that sensor 140 collects the plurality of time series signals in which each time series signal comprises a sequence of values that are captured over time, wherein the source of the plurality of signals varies from implementation to implementation (e.g., the databases). In some embodiments, the time series signals may be pre-processed by server 120 and the time series signals correspond to the plurality of windows of time. It should be understood that the purpose of the plurality of signals being pre-processed is to filter out noise resulting in clean signals being received by server 120. In some embodiments, the time series data may be assigned one or more timestamped scores via server 120.

Server 120 is further designed to generate a centralized platform configured to support receiving one or more inputs on computing devices associated with a plurality of users operating on the centralized platform. The centralized platform may support receiving supplemental data sourced from the plurality of users in order to edit and/or optimize data within one or more of the databases or data received by server 120. It should be noted that the centralized platform is configured to provide analytics associated with one or more data sources utilized by server 120 and/or outputs of server 120 and associated modules. For example, the centralized platform is configured to be the mechanism for server 120 to present one or more knowledge graphs and/or visualizations pertaining to geographic area 130 generated based on inferences/derivatives of the knowledge graphs on the applicable computing devices.

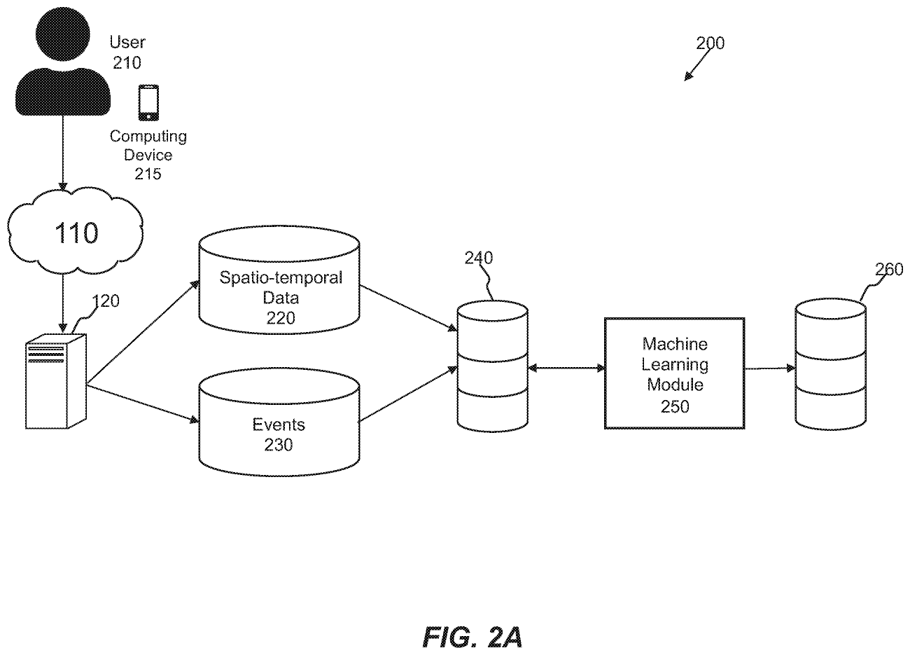

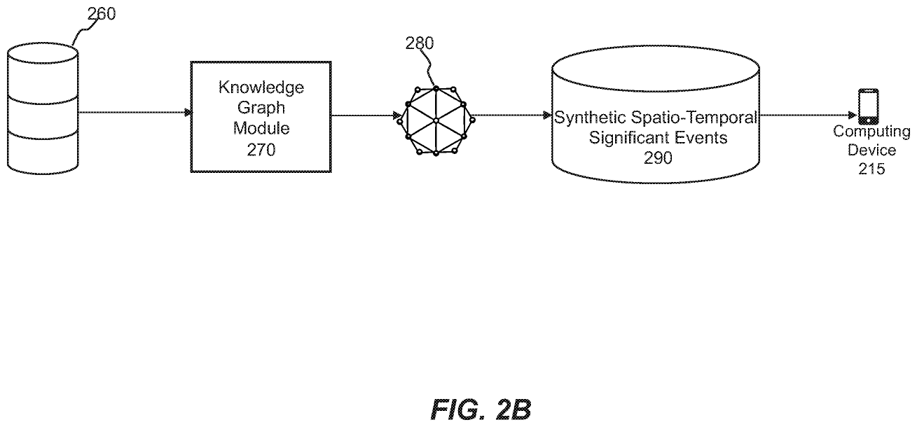

Referring now to FIGS. 2A-B, a data flow 200 associated with weather simulation environment 100 is depicted, according to an exemplary embodiment. In some embodiments, a user 210 associated with a computing device 215 communicatively coupled to server 120 over network 110 is configured to access the centralized platform. It should be noted that a significant purpose of the centralized platform is to allow user 210 to overview data being collected from one or more of sensor 140, stored in the databases, and/or transmitted to server 120 over network 110. In some embodiments, user 210, via computing device 215, may apply filters to aforementioned data received, apply edits to the plurality of control variables (e.g., data scientist responsibilities, etc.), and view/edit one or more graphical representations associated with geographic area 130 and/or derivatives thereof. User 210 may not only provide event descriptors to the plurality of events, but also ascertain strategic plans pertaining to social, political, economic, etc. impacts associated with geographic area 130 based on one or more outputs of the modules disclosed herein. Server 120 receives data over network 110 from one or more of sensor 140, the databases, and/or computing device 215. Server 120 is configured to filter the aforementioned received data in order to ascertain a plurality of spatio-temporal data associated with geographic area 130. For example, filtered data derived from topographic/urban database 160 and historical climate database 180 are integrated by server 120 and stored in a spatio-temporal database 220, and filtered event data derived from data feed database 150 and/or any of the other applicable sources is stored in an event data database 230. In some embodiments, spatio-temporal data derived from data ascertained by sensor 140 and/or the crowdsourcing/crowd-sharing platform pertaining to geographic area 130 allows server 120 to collect data provided by other sensor module/crowdsourcing platforms regarding spatio-temporal conditions at other locations, including locations that are proximate to geographic area 130. In some embodiments, server 120 is designed to perform a semantic analysis of collected data, progressively, as it is captured by sensor 140, and modify functions of sensor 140 when the program code identifies spatio-temporal environmental conditions within collected media. It should be noted that one of the significant purposes of server 120 performing semantic analysis is to derive data pertaining to the plurality of spatio-temporal data that impact geographic area 130, and when the plurality of spatio-temporal is stored in spatio-temporal database 220, the records saved by the program code are indexed by location, time, spatio-temporal analytics (e.g., level of impact of particular data on geographic area 130), and any other applicable metadata tags known to those of ordinary skill in the art. Event data derived from sources such as data feed 150 may be filtered and stored in event data database 230 via server 120 based on various factors including but not limited inputs of user 210, the amount of relevance to geographic area 130 (e.g., level of impact), the plurality of control variables, or any other applicable factors known to those of ordinary skill in the art. For example, user 210, via computing device 215, may apply filters pertaining to types of events that matter associated with geographic area 130 in which server 120 may apply the filters collected on the centralized platform to event data within event data database 230. In some embodiments, data within spatio-temporal database 220 and event data database 230 may be correlated and bounded into a spatio-temporal/event dataset 240 configured to be accessed by server 120. The purpose in associating the data within respective databases 220 and 230 into dataset 240 is to not only provide correlation of the filtered data into a singular repository, but also to provide a scalable manner for server 120 to access the bounded dataset for preparation of training datasets.

Server 120 is configured to be communicatively coupled to a machine learning module 250 which is designed to generate machine learning models trained based on one or more training data sets derived from spatio-temporal/event dataset 240, spatio-temporal database 220, event data database 230, and/or any other applicable data source of environment 100. In a preferred embodiment, machine learning module 250 is configured to utilize one or more machine learning algorithms to train time series deep learning models based on training sets derived from dataset 240, in which one or more spatio-temporal/relevant events dataset 260 are generated by the models. It should be noted that spatio-temporal/event dataset 240 may be created as a compilation of outputs of one or more models in which spatio-temporal/event dataset 240 may include a clustering of a plurality of events derived from data feed database 150; however, the clustering of the plurality events accounts for the time, location, content/context, etc. of each of the respective events in order to optimally correlate events to other data received by server 120 (e.g. data received from sensor 140, the databases, etc.). For example, one or more events may be clustered based on one or more similarities wherein the one or more similarities can be determined in terms of multiple measures including but not limited to Euclidean distance, Manhattan distance, dynamic time warping (DTW) distance, Minkowski Distance, Cosine distance, Correlation coefficients (e.g. Pearson, Spearman), or any other applicable similarity measure known to those of ordinary skill in the art. The clustering of the plurality of events may include one or more of K-means clustering or other centroid based clustering model, fuzzy c-means clustering, hierarchical clustering, distribution clustering models, density based clustering models such as, e.g., DBSCAN or OPTICS, HCS clustering, or neural network based models such as, e.g., self-organizing maps, or any other suitable clustering model. It should be noted that the one or more similarities may be derived from one or more components of the plurality of events in which the similarity between events of a cluster represents a shared or similar issue/solution (e.g, weather related condition), subject matter (e.g., content of news article pertaining to geographic location 130), and/or any other applicable component of the plurality of events. In some embodiments, events may be a cluster of a weighed textual descriptions ascertained by server 120, in which server 120 (alone or in combination with machine learning module 250) assigns a similarity score and at least a weight to each event. The similarity score serves as a mechanism to filter events from clusters in which server 120 removes events including a similarity score that fails to exceed a similarity threshold during the clustering process. The similarity threshold may be established by one or more of server 120, user 210 (via inputs on the centralized platform), and/or machine learning module 250. In some embodiments, a fuzzy c-mean algorithm or any other applicable clustering algorithm known to those of ordinary skill in the art is utilized to ascertain the at least one weight configured to indicate a degree of membership of the applicable point to the cluster. The weight may be a real number or limited to between 0 and 1.

It should be noted that the association of data within spatio-temporal database 220 and event data database 230 to create spatio-temporal/event dataset 240 may be accomplished by one or modules configured to bind geolocated textual time-series data derived from the databases and/or crowdsourcing/crowd-sharing platforms with spatio-temporal integrated data; however, filtering of resulting integration and dataset generation is necessary in order to account for definitions of relevant events associated with geographic location 130 defined by user 210. In some embodiments, spatio-temporal/event dataset 240 is utilized for training sets by machine learning module 250 in order to generate a spatio-temporal/relevant events dataset 260 which may be an aggregation of the one or more outputs of machine learning module 250. Spatio-temporal/relevant events dataset 260 includes one or more components of the plurality of events in which the one or more components may be a cluster of geolocated textual data at a particular time whose elements have a weight and similarity score that exceeds the similarity threshold. In some embodiments, data within spatio-temporal/relevant events dataset 260 includes the one or more outputs of machine learning module 250 in which the spatio-temporal/relevant events dataset 260 may be utilized for training sets in future iterations.

In some embodiments, spatio-temporal/relevant events dataset 260 are utilized by a knowledge graph module 270 in order for knowledge graph module 270 to generate one or more knowledge graphs 280 associated with geographic location 130. It should be noted that machine learning module 250 is configured to provide weights associated with spatio-temporal/relevant events dataset 260 allowing server 120 to prioritize data utilized by machine learning module 250 based on the level of the impact of the particular data on geographic location 130 directly or indirectly. For example, various factors that are ascertainable from the data utilized by machine learning module 250 such as precipitation intensity/frequency, economical impact on geographic location 130, etc. may be prioritized by server 120 via one or more iterations performed by machine learning module 250. By using diverse sets of training data derived from the bounded spatio-temporal/event dataset 240, machine learning module 250 may be configured to train the models to identify and weigh various attributes that correlate to various components of dataset 240 such as features, patterns, etc. For example, the correlation between flash floods and traffic jams within geographic location 130 may be ascertained from one or more iterations performed by machine learning module 250. In some embodiments, knowledge graph module 260 include a plurality of spatio-temporal data based on the association in which the plurality of spatio-temporal data includes a plurality of geospatial data associated with geographic area 130. The spatio-temporal data may be utilized by knowledge graph module 270 to generate the knowledge graphs and/or the knowledge graphs may include the spatio-temporal data.

It should further be noted that filters provided by user 210 (via the user inputs on the centralized platform) along with the plurality of control variables may be integrated into the one or more iterations performed by machine learning module 250, allowing filtering and fine-tuning of the datasets that not only supports rendering of the optimized knowledge graphs via knowledge graph module 260, but also more efficient and accurate weather simulations of geographic location 130 based on the optimized knowledge graphs. For example, the plurality of control variables and one or more weather projections derived from historical climate database 180 may be integrated into subsequent iterations via utilization of an adaptive control module or any other applicable module known to those of ordinary skill in the art. In some embodiments, knowledge graphs 280 include one or more simulations configured to support generation of simulated spatio-temporal significant events 290. Simulated spatio-temporal significant events 290 may include a plurality of inferences or may be configured to support interaction with user 215 by presentation of graphical interfaces to computing device 215 via the centralized platform. Visual depictions of synthetic spatio-temporal significant events 290 may be manifested in any applicable manner known to those of ordinary skill in the art including but not limited to graphs, maps, charts, etc.

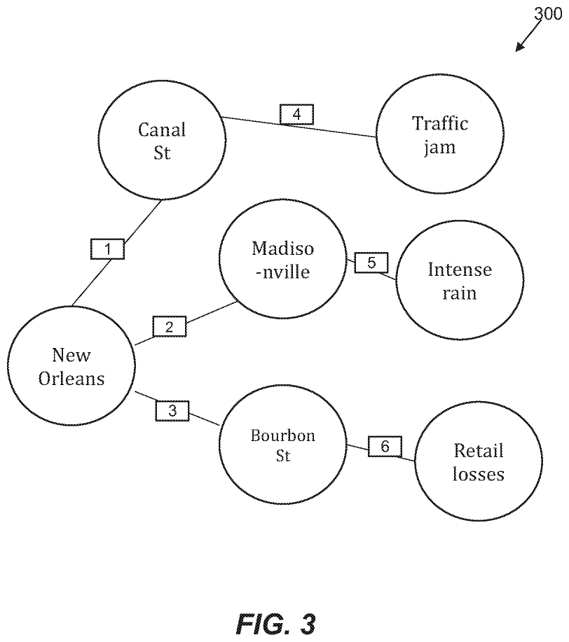

Referring now to FIG. 3, a resulting knowledge graph 300 generated by knowledge graph module 270 is depicted, according to an exemplary embodiment. In some embodiments, knowledge graph 300 includes a plurality of nodes and edges in which edges may link nodes. Edges may include a plurality of attributes and nodes may include facts associated with geographic location 130. Knowledge graph module 270 may support generation of sub-knowledge graphs along with other applicable knowledge graph functionalities such as partitioning, cluster cores, and any other applicable features known to those of ordinary skill in the art. In some embodiments, the edges may be associated with characteristics/features such as numbers indicating search path frequencies, unique identification numbers (ID), and any other applicable parameter. In some embodiments, the frequency of the applicable edge of graph 300 may form the center of a subgraph of graph 300, and the radius pertains to the total size of the knowledge graph. It should be noted that the knowledge graph is configured to be utilized to ascertain one or more inferences pertaining to geographic location 130 in which knowledge graph 300 includes at least one synthesis configured to support generation of a weather simulation for a period time associated with geographic location 130. In some embodiments, knowledge graph 300 may be associated with one or more queries of user 210 in which knowledge graph 300 is constructed based on one or more simulations rendered by knowledge graph module 270. For example, knowledge graph module 270 and/or server 120 may discover the K most similar knowledge graph to the simulations. In some embodiments, statistical models may be applied in order to process the queries in which the processing may include but is not limited to counting the frequencies of terms and links provided by knowledge graph 300. In an exemplary reference to knowledge graph 300 as depicted, the aforementioned processing allows statistical models, such as a Bayesian network, to respond to queries such as “Given an intense rain in this location, what is the probability of causing flood with retail losses in this street?”.

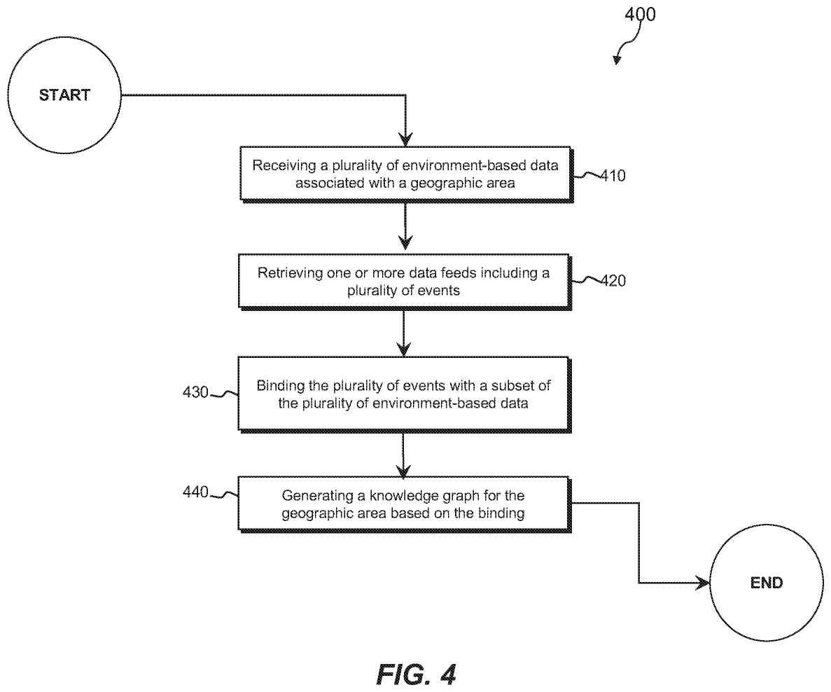

Referring now to FIG. 4, an operational flowchart illustrating an exemplary process for generating weather simulations based on significant events 400 is depicted according to at least one embodiment.

At step 410 of process 400, server 120 receives the plurality of environmental data associated with geographic area 130. In a preferred embodiment, server 120 receives the plurality of environmental data from one or more of sensor 140, crowdsourcing/crowd-sharing platform, and/or the databases. It should be noted that as server 120 is receiving the plurality of environmental data, it is possible for server 120 to receive the one or more inputs from user 210 via the centralized platform.

At step 420 of process 400, server 120 retrieve one or more data feeds from data feed database 150. It should be noted that the purpose of retrieving the one or more data feeds is for server 120 to ascertain the plurality of events associated with geographic location 130. In some embodiments, the one or more crawlers may access data within data feed database 150 and extract social media content and/or internet-based content and select data for transmission to server 120 based on metadata within the social media content and/or internet-based content indicating that the content is associated with geographic location 130. Relevance, frequency, and priority of data of the events may be significant factors in the type/order of data selected by server 120 to be utilized by machine learning module 250 within the training data sets.

At step 430 of process 400, server 120 with the assistance of machine learning module 250 binds the plurality of events ascertained via step 420 with one or more subsets of the plurality of environment-data. In some embodiments, the association and/or synthesis of the data may be generally based on filters applied by user 210 in addition to the plurality of control variables; however, the layered generation of data sets 240 and spatio-temporal/relevant events dataset 260 serve as results of the one or more iterations of machine learning module 250 associating data collected within environment 100 in order to generate classifications and correlations between the plurality of events and the plurality of environment-data. As previously mentioned, the similarity scores assigned to events facilitate the metric for grouping and removing events, and in instances in which user 210 provides one or more event descriptors for events within the plurality of events that do not have relevant data readily ascertainable, the event descriptors serve as additional filters to ascertain the events most relevant to geographic location 130.

At step 440 of process 400, knowledge graph module 270 generates the knowledge graph pertaining to geographic location 130 based on the association process of step 430. In some embodiments, knowledge graph module 270 generates the knowledge graphs based on spatio-temporal/relevant events dataset 260 in which the knowledge graphs include one or more syntheses configured to support generation of a weather simulation for a period of time associated with geographic location 130. In some embodiments, analytics algorithms may be utilized in order to obtain metrics from the knowledge graphs. It should be noted that the knowledge graphs and mechanisms derived from the knowledge graphs are configured to be viewed and analyzed by user 210 on the centralized platform; however, one of the most significant purposes of the knowledge graphs is to allow server 120 to generate synthetic spatio-temporal significant events 290. In some embodiments, the knowledge graphs are configured to be utilized by various software including but not limited to risk analyzers, warning systems, disaster counter-measure/prevention systems, and other applicable software. In particular, the knowledge graphs are designed to reduce uncertainty associated with downstream applications by incrementing precision relating to weather analyses and predictions.

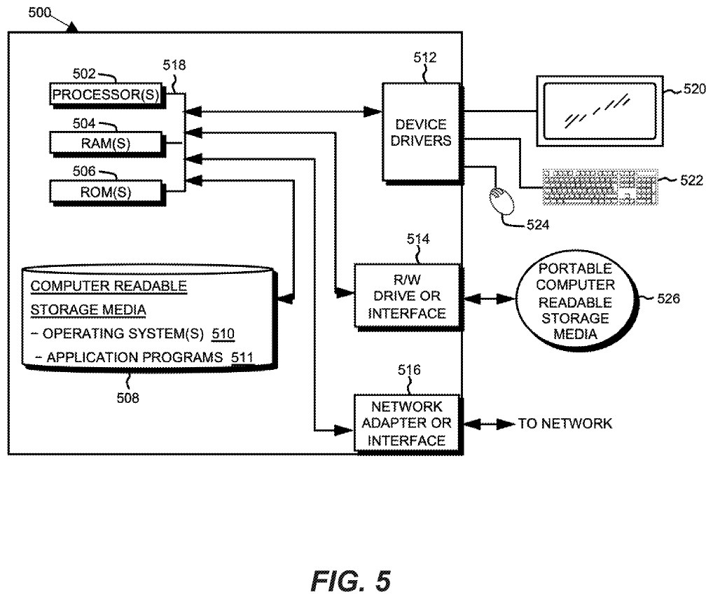

FIG. 5 is a block diagram of components 500 of computers depicted in FIG. 1 in accordance with an illustrative embodiment of the present invention. It should be appreciated that FIG. 5 provides only an illustration of one implementation and does not imply any limitations with regard to the environments in which different embodiments may be implemented. Many modifications to the depicted environments may be made based on design and implementation requirements.

Data processing system 502, 504 is representative of any electronic device capable of executing machine-readable program instructions. Data processing system 502, 504 may be representative of a smart phone, a computer system, PDA, or other electronic devices. Examples of computing systems, environments, and/or configurations that may represented by data processing system 502, 504 include, but are not limited to, personal computer systems, server computer systems, thin clients, thick clients, hand-held or laptop devices, multiprocessor systems, microprocessor-based systems, network PCs, minicomputer systems, and distributed cloud computing environments that include any of the above systems or devices.

The one or more servers may include respective sets of components illustrated in FIG. 5. Each of the sets of components include one or more processors 502, one or more computer-readable RAMs 508 and one or more computer-readable ROMs 510 on one or more buses 502, and one or more operating systems 514 and one or more computer-readable tangible storage devices 516. The one or more operating systems 514 and computing event management system 210 may be stored on one or more computer-readable tangible storage devices 516 for execution by one or more processors 502 via one or more RAMs 508 (which typically include cache memory). In the embodiment illustrated in FIG. 5, each of the computer-readable tangible storage devices 516 is a magnetic disk storage device of an internal hard drive. Alternatively, each of the computer-readable tangible storage devices 516 is a semiconductor storage device such as ROM 510, EPROM, flash memory or any other computer-readable tangible storage device that can store a computer program and digital information.

Each set of components 500 also includes a R/W drive or interface 514 to read from and write to one or more portable computer-readable tangible storage devices 508 such as a CD-ROM, DVD, memory stick, magnetic tape, magnetic disk, optical disk or semiconductor storage device. A software program, such as computing event management system 210 can be stored on one or more of the respective portable computer-readable tangible storage devices 508, read via the respective RAY drive or interface 518 and loaded into the respective hard drive.

Each set of components 500 may also include network adapters (or switch port cards) or interfaces 516 such as a TCP/IP adapter cards, wireless wi-fi interface cards, or 3G or 4G wireless interface cards or other wired or wireless communication links. COP 120 can be downloaded from an external computer (e.g., server) via a network (for example, the Internet, a local area network or other, wide area network) and respective network adapters or interfaces 516. From the network adapters (or switch port adaptors) or interfaces 516, the centralized platform is loaded into the respective hard drive 508. The network may comprise copper wires, optical fibers, wireless transmission, routers, firewalls, switches, gateway computers and/or edge servers.

Each of components 500 can include a computer display monitor 520, a keyboard 522, and a computer mouse 524. Components 500 can also include touch screens, virtual keyboards, touch pads, pointing devices, and other human interface devices. Each of the sets of components 500 also includes device processors 502 to interface to computer display monitor 520, keyboard 522 and computer mouse 524. The device drivers 512, R/W drive or interface 518 and network adapter or interface 518 comprise hardware and software (stored in storage device 504 and/or ROM 506).

It is understood in advance that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Analytics as a Service (AaaS): the capability provided to the consumer is to use web-based or cloud-based networks (i.e., infrastructure) to access an analytics platform. Analytics platforms may include access to analytics software resources or may include access to relevant databases, corpora, servers, operating systems or storage. The consumer does not manage or control the underlying web-based or cloud-based infrastructure including databases, corpora, servers, operating systems or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

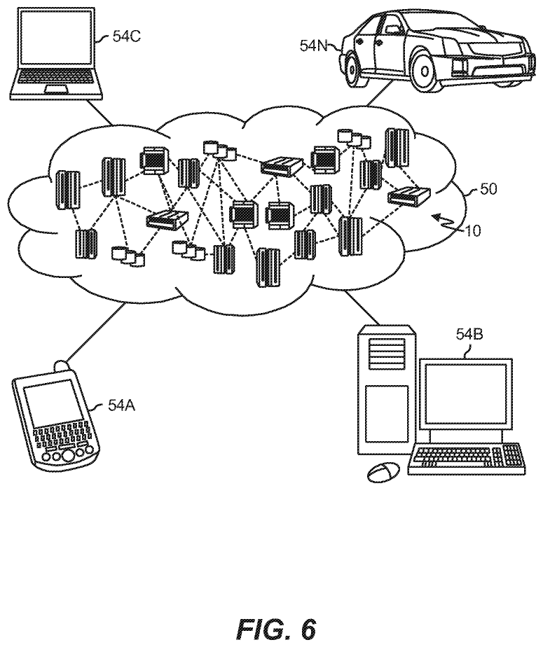

Referring now to FIG. 6, illustrative cloud computing environment 600 is depicted. As shown, cloud computing environment 600 comprises one or more cloud computing nodes 6000 with which local computing devices used by cloud consumers, such as, for example, personal digital assistant (PDA) or cellular telephone 6000A, desktop computer 6000B, laptop computer 6000C, and/or automobile computer system 6000N may communicate. Nodes 6000 may communicate with one another. They may be grouped (not shown) physically or virtually, in one or more networks, such as Private, Community, Public, or Hybrid clouds as described hereinabove, or a combination thereof. This allows cloud computing environment 6000 to offer infrastructure, platforms and/or software as services for which a cloud consumer does not need to maintain resources on a local computing device. It is understood that the types of computing devices 6000A-N shown in FIG. 6 are intended to be illustrative only and that computing nodes 6000 and cloud computing environment 600 can communicate with any type of computerized device over any type of network and/or network addressable connection (e.g., using a web browser).

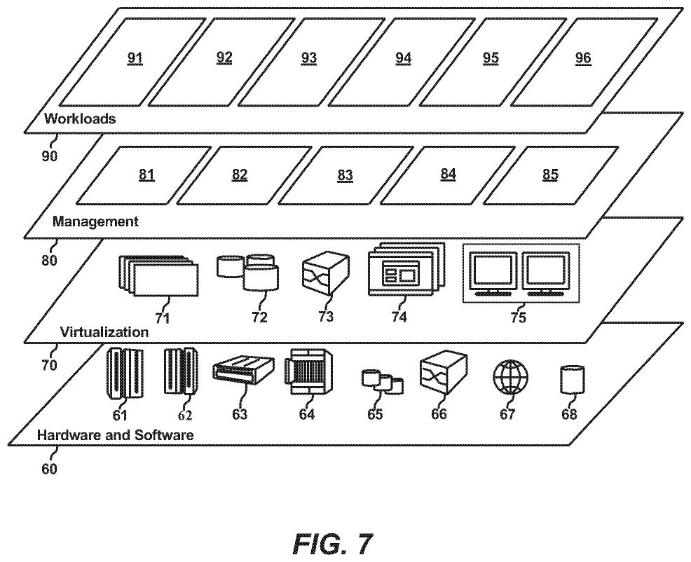

Referring now to FIG. 7 a set of functional abstraction layers provided by cloud computing environment 600 (FIG. 6) is shown. It should be understood in advance that the components, layers, and functions shown in FIG. 7 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 66 and database software 68.

Virtualization layer 60 provides an abstraction layer from which the following examples of virtual entities may be provided: virtual servers 61; virtual storage 62; virtual networks 63, including virtual private networks; virtual applications and operating systems 64; and virtual clients 65.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; and transaction processing 95.

Based on the foregoing, a method, system, and computer program product have been disclosed. However, numerous modifications and substitutions can be made without deviating from the scope of the present invention. Therefore, the present invention has been disclosed by way of example and not limitation.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” “including,” “has,” “have,” “having,” “with,” and the like, when used in this specification, specify the presence of stated features, integers, steps, operations, elements, and/or components, but does not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

It will be appreciated that, although specific embodiments have been described herein for purposes of illustration, various modifications may be made without departing from the spirit and scope of the embodiments. In particular, transfer learning operations may be carried out by different computing platforms or across multiple devices. Furthermore, the data storage and/or corpus may be localized, remote, or spread across multiple systems. Accordingly, the scope of protection of the embodiments is limited only by the following claims and their equivalent.

What is claimed is:

1. A computer-implemented method for simulating weather, the method comprising:
receiving, by a computing device, a plurality of environmental data associated with a geographic area;
retrieving, by the computing device, one or more data feeds including a plurality of real-time events;
associating, by the computing device, the plurality of real-time events with a subset of the plurality of environmental data; and
generating, by the computing device, a knowledge graph for the geographic area based on the association.

2. The computer-implemented method of claim 1, wherein the knowledge graph is configured to support generation of a weather simulation associated with the geographic area for a period of time in the future.

3. The computer-implemented method of claim 1, wherein retrieving one or more data feeds comprises:
extracting, via the computing device, the plurality of real-time events based on metadata indicating the plurality of real-time events pertain to the geographic area; and
clustering, via the computing device, the plurality of real-time events based on a similarity threshold;
wherein the metadata is derived from at least one piece of social media content.

4. The computer-implemented method of claim 3, wherein associating the plurality of events with the subset of the plurality of environmental data comprises:
assigning, via the computing device, a similarity score and at least a weight to each event of the plurality of events; and
removing, via the computing device, events of the plurality of events that fail to exceed the similarity threshold.

5. The computer-implemented method of claim 1, wherein association of the plurality of events with the subset of the plurality of environmental data comprises:
receiving, via the computing device, at least one event descriptor associated with an event of the plurality of events from a user; and
filtering, via the computing device, the plurality of events based on the least one event descriptor.

6. The computer-implemented method of claim 1, wherein association of the plurality of events with the subset of the plurality of environmental data comprises:
generating, via the computing device, a machine learned model based on training data sets including the plurality of environmental data and the plurality of events;
wherein the machine learned model is configured to generate an output designed to be utilized by the computing device to generate the knowledge graph.

7. The computer-implemented method of claim 1, wherein generating the knowledge graph comprises:
accessing, via the computing device, a plurality of spatio-temporal data based on the association; and
generating, via the computing device, the knowledge graph wherein the knowledge graph includes the plurality of spatio-temporal data including a plurality of geospatial data associated with the geographic area.

8. The computer-implemented method of claim 1, wherein the plurality of environmental data includes at least one of historical climate data, crowdsourcing data, topographic/urban data, forecasting weather projections, and control variables.

9. The computer-implemented method of claim 1, wherein the one or more data feeds originate at least from one of social media content and internet-based content.

10. A computer program product using a computing device for simulating weather, the computer program product comprising:
one or more non-transitory computer-readable storage media and program instructions stored on the one or more non-transitory computer-readable storage media, the program instructions, when executed by the computing device, cause the computing device to perform a method comprising:
receiving, by a computing device, a plurality of environmental data associated with a geographic area;
retrieving, by the computing device, one or more data feeds including a plurality of real-time events;
associating, by the computing device, the plurality of real-time events with a subset of the plurality of environmental data; and
generating, by the computing device, a knowledge graph for the geographic area based on the association.

11. The computer program product of claim 10, wherein the knowledge graph is configured to support generation of a weather simulation associated with the geographic area for a period of time in the future.

12. The computer program product of claim 10, wherein retrieving one or more data feeds by computing device comprises:
extracting the plurality of real-time events based on metadata indicating the plurality of real-time events pertain to the geographic area; and
clustering the plurality of real-time events based on a similarity threshold;
wherein the metadata is derived from at least one piece of social media content.

13. The computer program product of claim 10, wherein associating the plurality of events with the subset of the plurality of environmental data by the computing device comprises:
assigning a similarity score and at least a weight to each event of the plurality of events; and
removing events of the plurality of events that fail to exceed the similarity threshold.

14. The computer program product of claim 10, wherein associating of the plurality of events with the subset of the plurality of environmental data by the computing device comprises:
receiving at least one event descriptor associated with an event of the plurality of events from a user; and
filtering the plurality of events based on the least one event descriptor.

15. The computer program product of claim 10, wherein associating of the plurality of events with the subset of the plurality of environmental data by the computing device comprises:
generating a machine learned model based on training data sets including the plurality of environmental data and the plurality of events;
wherein the machine learned model is configured to generate an output designed to be utilized by the computing device to generate the knowledge graph.

16. The computer program product of claim 10, wherein generating the knowledge graph by the computing device comprises:
accessing a plurality of spatio-temporal data based on the association; and
generating the knowledge graph wherein the knowledge graph includes the plurality of spatio-temporal data including a plurality of geospatial data associated with the geographic area.

17. The computer program product of claim 10, wherein the plurality of environmental data includes at least one of historical climate data, crowdsourcing data, topographic/urban data, forecasting weather projections, and control variables.

18. The computer program product of claim 10, wherein the one or more data feeds originate at least from one of social media content and internet-based content.

19. A computer system for simulating weather, the computer system comprising:
one or more processors, one or more computer-readable memories, and program instructions stored on at least one of the one or more computer-readable memories for execution by at least one of the one or more processors to cause the computer system to:
program instructions to receive a plurality of environmental data associated with a geographic area;
program instructions to retrieve one or more data feeds including a plurality of real-time events;
program instructions to associate the plurality of real-time events with a subset of the plurality of environmental data; and
generate a knowledge graph for the geographic area based on the association.

20. The computer system of claim 19, wherein program instruction to generate the knowledge graph further comprises program instructions to:
access a plurality of spatio-temporal data based on the association; and
generate the knowledge graph wherein the knowledge graph includes the plurality of spatio-temporal data including a plurality of geospatial data associated with the geographic area.
